(19) United States
(12) Patent Application Publication
(10) Pub. No.: US 2026/0190484 A1
(43) Pub. Date: Jul. 2, 2026

(54) ARRAY SUBSTRATE, DISPLAY PANEL, AND DISPLAY APPARATUS

(71) Applicants: Beijing BOE Display Technology Co., Ltd., Beijing (CN); BOE Technology Group Co., Ltd., Beijing (CN)

(72) Inventors: Yihe JIA, Beijing (CN); Xiangqian DING, Beijing (CN); Weitao CHEN, Beijing (CN); Hui GUO, Beijing (CN); Jing LIU, Beijing (CN); Xiaoying LI, Beijing (CN); Yan YAN, Beijing (CN); Haipeng LIU, Beijing (CN); Xinxin SHAO, Beijing (CN); Haoxiong ZHANG, Beijing (CN); Yanxin JI, Beijing (CN); Jie GAO, Beijing (CN); Xiao HAN, Beijing (CN); Mengnan WANG, Beijing (CN); Yongzhi SONG, Beijing (CN); Yu MA, Beijing (CN); Bin DONG, Beijing (CN); Yulong HU, Beijing (CN); Jiantao LIU, Beijing (CN); Yan PANG, Beijing (CN)

(21) Appl. No.: 18/728,544

(22) PCT Filed: Mar. 23, 2023
(86) PCT No.: PCT/CN2023/083491

§ 371 Date: Jul. 12, 2024

(51) Int. Cl. H10D 86/40; G02F 1/1362; H10D 86/60

(52) U.S. Cl. CPC H10D 86/441; G02F 1/136286; H10D 86/60

(57) ABSTRACT

Array substrate, display panel and display apparatus are disclosed. The array substrate includes: a base substrate, including sub-pixel areas arranged in an array, and a first area between adjacent sub-pixel areas; scanning lines, at a side of the base substrate and in the first area; first pixel electrodes, at a side of the scanning line facing away from the base substrate; where each of the plurality of first pixel electrodes includes: a first portion; and a second portion and a third portion at two sides of the first portion in the second direction. An orthographic projection of the first portion and an orthographic projection of the scanning line on the base substrate have an overlapping area; and an orthographic projection of the second portion and an orthographic projection of the third portion on the base substrate are arranged at two sides of the scanning line.

### CROSS REFERENCE TO RELATED APPLICATIONS

This application is a national phase entry under 35 U.S.C. § 371 of International Application No. PCT/CN2023/083491, filed on Mar. 23, 2023, the entire content of which is incorporated herein by reference.

### TECHNICAL FIELD

The disclosure relates to the field of display technology, and in particular to an array substrate, a display panel, and a display apparatus.

### BACKGROUND

With the continuous development and application of display technology, users have increasingly high requirements for the display effect of electronic display products. At present, liquid crystal display products adopt the dual gate design to reduce costs. However, due to the parasitic capacitance between the pixel electrodes and the gate lines, when the pixel electrodes corresponding to various sub-pixels are shifted upwards or downwards as a whole due to process deviation, it will lead to a significant difference in parasitic capacitance between different pixel electrodes and difference in charging rates between different pixel electrodes, resulting in differences in brightness among different sub pixels. When the user moves and watches the display product, such as shaking their head, the brightness of brighter sub-pixels overlaps with each other, and the brightness of darker sub-pixels also overlaps with each other, causing the difference in brightness to get worse, resulting in shake-head stripe that affect the display effect of the display product.

### SUMMARY

Embodiments of the disclosure provide an array substrate, the array substrate includes: a base substrate, including a plurality of sub-pixel areas arranged in an array, and a first area between adjacent sub-pixel areas; a plurality of scanning lines, at a side of the base substrate and in the first area; where the plurality of scanning lines extend in a first direction, and are arranged in a second direction, the first direction intersects with the second direction; a plurality of first pixel electrodes, at a side of the scanning line facing away from the base substrate; where each of the plurality of first pixel electrodes includes: a first portion; and a second portion and a third portion at two sides of the first portion in the second direction; where an orthographic projection of the first portion on the base substrate and an orthographic projection of the scanning line on the base substrate have an overlapping area; and an orthographic projection of the second portion on the base substrate and an orthographic projection of the third portion on the base substrate are arranged at two sides of the scanning line, respectively.

In some embodiments, the array substrate further includes: a plurality of first thin-film transistors, in the first area and at a side of the base substrate same as the scanning line; where the first thin-film transistor includes a first electrode, a second electrode, and a third electrode; the first electrode is electrically connected with the scanning line, and the third electrode is electrically connected with the first pixel electrode. In the second direction, the third electrode of the first thin-film transistor and the third portion are arranged at the same side of the scanning line connected with the first thin-film transistor; the orthographic projection of the third portion on the base substrate and an orthographic projection of the third electrode on the base substrate have an overlapping area; and the third portion is electrically connected with the third electrode.

In some embodiments, the third electrode includes a first strip portion extending in the first direction, and the third portion includes a second strip portion extending in the first direction; and an orthographic projection of the second strip portion on the base substrate and an orthographic projection of the first strip portion on the base substrate have an overlapping area.

In some embodiments, the orthographic projection of the second strip portion on the base substrate covers the orthographic projection of the first strip portion on the base substrate.

In some embodiments, the second strip portion wraps around a side surface of the first strip portion.

In some embodiments, the orthographic projection of the third portion on the base substrate and an orthographic projection of the first electrode on the base substrate do not overlap with each other.

In some embodiments, in the first direction, the second portion and the third portion are respectively arranged at two sides of the first portion.

In some embodiments, the plurality of sub-pixel areas are divided into a plurality of sub-pixel area columns, and the plurality of sub-pixel area columns extend in the second direction and are arranged in the first direction; the orthographic projection the first strip portion on the base substrate passes through an area between two adjacent sub-pixel area columns; in the first pixel electrode and the first thin-film transistor electrically connected with each other, the first electrode and the second portion correspond to two different sub-pixel area columns that adjacent to each other, respectively.

In some embodiments, the array substrate further includes: a plurality of data lines in the first area, where the plurality of data lines are arranged between the scanning lines and the pixel electrodes in a direction perpendicular to the base substrate; the plurality of data lines extend in the second direction, and arranged in the first direction; two sub-pixel area columns are located between two adjacent data lines, and the second electrode is electrically connected with the data line; and the first thin-film transistor and the first pixel electrode electrically connected with the first thin-film transistor are located between the two adjacent data lines.

In some embodiments, the plurality of scanning lines include a plurality of first scanning lines and a plurality of second scanning lines; the first scanning line and the second scanning line are arranged alternately; and one first scanning line and one second scanning line are arranged between two adjacent sub-pixel areas in the second direction; and between two adjacent data lines and in the first area, two first pixel electrodes respectively corresponding to adjacent first scanning line and second scanning line are located in different sub-pixel area columns.

In some embodiments, between two adjacent data lines and in the first area corresponding to the first thin-film transistor, the scanning line includes a third strip portion extending in the first direction; and an edge of the second portion close to the third strip portion is parallel to the third strip portion.

In some embodiments, in the second direction, a distance between the third portion and the scanning line is approximately equal to a distance between the second portion and the scanning line.

In some embodiments, an edge of the first electrode close to the third portion is perpendicular to the third strip portion; between two adjacent said data lines and between two adjacent sub-pixel area rows, two first electrodes electrically connected with the first scanning line and the second scanning line respectively are arranged opposite to each other in the first direction; an orthographic projection of the first strip portion on the base substrate and the orthographic projection of the second strip portion on the base substrate are located between orthographic projections of the two first electrodes opposite to each other on the base substrate.

In some embodiments, the scanning line further includes: a first widening portion connected with the third strip portion in the second direction; and the first widening portion is arranged at the same side of the third strip portion as the third portion. In the first direction, an orthographic projection of the first widening portion on the base substrate and an orthographic projection of the first electrode on base substrate are respectively located at two sides of an orthographic projection of the first strip portion on the base substrate; the orthographic projection of the first widening portion on the base substrate and the orthographic projection of the first electrode on base substrate do not overlap with each other; between two adjacent date lines and between adjacent sub-pixel area rows, the orthographic projection of the first widening portion on the base substrate is located between orthographic projections of the two first electrodes arranged opposite to each other on the base substrate.

In some embodiments, the array substrate further includes: a plurality of second thin-film transistors, where each second thin-film transistor includes a fourth electrode, a fifth electrode and a sixth electrode; a length of the sixth electrode is less than a length of the third electrode in the first direction; the fourth electrode is electrically connected with the scanning line, and the fifth electrode is electrically connected with the data line; and a plurality of second pixel electrodes; where an orthographic projection of the second pixel electrode on the base substrate and an orthographic projection of the scanning line on the base substrate do not overlap with each other; and the second pixel electrode is electrically connected with the sixth electrode; where the second pixel electrode and the second thin-film transistor electrically connected with the second pixel electrode correspond to the same one sub-pixel area column.

In some embodiments, between two adjacent data lines and in the first area corresponding to the second thin-film transistor, a pattern formed by an orthographic projection of the scanning line on the base substrate and an orthographic projection of the fourth electrode on the base substrate has a first concave area; an orthographic projection of the sixth electrode on the base substrate and the first concave area have an overlapping area, and the sixth electrode is electrically connected with the second pixel electrode in the first concave area.

In some embodiments, the sixth electrode includes a convex portion, an orthographic projection of the convex portion on the base substrate and an orthographic projection of the fourth electrode at a side of the first concave area facing away from the fifth electrode on the base substrate have an overlapping area.

In some embodiments, between two adjacent data lines and in the first area corresponding to the second thin-film transistor, the scanning line includes: a second widening portion, and a fourth strip portion extending in the first direction; the fourth electrode and the second widening portion are respectively at two sides of the first concave area in the first direction, and the fourth strip portion is arranged at a side of the second widening portion facing away from the first concave area; and a width of the second widening portion is greater than a width of the fourth strip portion in the second direction.

In some embodiments, between two adjacent data lines and in the first area corresponding to at least part of the second thin-film transistors, the scanning line further includes: a fifth strip portion connected with the second widening portion and the fourth strip portion; an angle between an extension direction of the fifth strip portion and the first direction is greater than 0, and an angle between the extension direction of the fifth strip portion and the second direction is greater than 0; a pattern formed by an orthographic projection of the second widening portion on the base substrate and an orthographic projection of the fifth strip portion on the base substrate has a second concave area; an orthographic projection of the second concave area on the base substrate and the orthographic projection of the fifth strip portion on the base substrate overlap with an area between two adjacent sub-pixel area columns.

In some embodiments, between two adjacent data lines and in the first area corresponding to at least part of the second thin-film transistors, the second widening portion is connected with the fourth strip portion; and at s side of the scanning line close to the sub-pixel area, an edge of the second widening portion is located in the same straight line as an edge of the fourth strip portion.

In some embodiments, a maximum width of the second widening portion is equal to a width of the fourth electrode in the second direction.

In some embodiments, the array substrate further includes: common electrode lines, and a common electrode electrically connected with the common electrode lines. The common electrode lines include: a plurality of first common electrode lines extending in the second direction; an orthographic projection of the common electrode line on the base substrate is located between two adjacent sub-pixel areas in the first direction; the common electrode includes: a plurality of sub-common electrodes, and a plurality of first connection portions; the sub-commons electrodes correspond to sub-pixel area rows, the first connection portion extends in the second direction, and the first connection portion is electrically connected with the sub-commons electrode.

In some embodiments, the orthographic projection of the scanning line on the base substrate includes a second concave area, an orthographic projection of at least part of the first connection portions on the base substrate and the orthographic projection of the second concave area on the base substrate have an overlapping area.

In some embodiments, the scanning line includes the second widening portion, the orthographic projection of at least part of the first connection portions on the base substrate and the orthographic projection of second widening portion on the base substrate have an overlapping area.

In some embodiments, at least part of the first common electrode lines includes: a second connection portion; the array substrate further includes an insulation layer arranged between the first common electrode line and the common electrode; the first connection portion is electrically connected with the second connection portion through a first via through the insulation layer; an orthographic projection of the first via on the base substrate does not completely overlap with an orthographic projection of the second connection portion on the base substrate.

In some embodiments, the first area includes a plurality of first area rows extending in the first direction and arranged in the second direction; each first area row includes: a plurality of repeating units arranged in the first direction; each repeating unit includes at least one first sub-area and at least one second sub-area arranged in the first direction, both the first sub-area and the second sub-area are located between two adjacent data lines; and only the first thin-film transistor is provided in each first sub-area, and only the second thin-film transistor is provided in each second sub-area.

In some embodiments, the repeating unit in odd-numbered rows of the first area rows includes m first sub-areas and n second sub-areas, and the repeating unit in even-numbered rows of the first area rows includes n first sub-areas and m second sub-areas; between two adjacent data lines, the first sub-area and the second sub-area are alternately arranged in the second direction.

In some embodiments, the repeating unit in the odd-numbered rows of the first area rows includes two first sub-areas and one second sub-area, and the repeating unit in the even-numbered rows of the first area rows includes one first sub-area and two second sub-areas.

In some embodiments, the first pixel electrode and the second pixel electrode are arranged at intervals from each other in the first direction.

Embodiments of the disclosure provide a display panel, the display panel includes: the array substrate provided by embodiments of the disclosure; an opposing substrate, arranged opposite to the array substrate; and a liquid crystal layer, arranged between the array substrate and the opposing substrate.

In some embodiments, the array substrate includes a plurality of scanning lines, the plurality of scanning lines include a plurality of second widening portions; the opposing substrate includes a plurality of spacers; an orthographic projection of the spacer on the base substrate included in the array substrate is located within an orthographic projection of the second widening portion on the base substrate.

Embodiments of the disclosure provide a display apparatus, the display apparatus includes the display panel provided by embodiments of the disclosure.

### BRIEF DESCRIPTION OF FIGURES

In order to more clearly illustrate the technical solutions in embodiments of the disclosure, a brief introduction will be given below to the drawings needed to be used in the description of embodiments. Obviously, the drawings in the following description are only some embodiments of the disclosure. Those of ordinary skill in the art can also obtain other drawings based on these drawings without exerting creative efforts.

FIG. 1 shows a schematic structural diagram of an array substrate provided by embodiments of the disclosure.

FIG. 2 shows a schematic structural diagram of an array substrate provided by the related art.

FIG. 3 shows a schematic diagram of the parasitic capacitance formed by the pixel electrode and the scanning line provided by embodiments of the disclosure.

FIG. 4 shows a cross-sectional view along AA′ in FIG. 1 provided by embodiments of the disclosure.

FIG. 5 shows a cross-sectional view along BB′ in FIG. 1 provided by embodiments of the disclosure.

FIG. 6 shows another schematic structural diagram of an array substrate provided by embodiments of the disclosure.

FIG. 7 shows another schematic structural diagram of an array substrate provided by embodiments of the disclosure.

FIG. 8 shows another schematic structural diagram of an array substrate provided by embodiments of the disclosure.

FIG. 9 shows a schematic structural diagram of a first conductive layer provided by embodiments of the disclosure.

FIG. 10 shows a schematic structural diagram of a second conductive layer provided by embodiments of the disclosure.

FIG. 11 shows a schematic structural diagram of a first pixel electrode and a second pixel electrode provided by embodiments of the disclosure.

FIG. 12 shows a schematic structural diagram of a common electrode provided by embodiments of the disclosure.

FIG. 13 shows an enlarged view of area E in FIG. 9 provided by embodiments of the disclosure.

FIG. 14 shows a cross-sectional view along CC′ in FIG. 8 provided by embodiments of the disclosure.

FIG. 15 shows a schematic structural diagram of a display panel provided by embodiments of the disclosure.

FIG. 16 shows a schematic structural diagram of an opposing substrate provided by embodiments of the disclosure.

FIG. 17 shows another schematic structural diagram of a display panel provided by embodiments of the disclosure.

### DETAILED DESCRIPTION

In order to make the purpose, technical solutions and advantages of embodiments of the disclosure more clear, the technical solutions of the embodiments of the disclosure will be clearly and completely described below in conjunction with the drawings of embodiments of the disclosure. Obviously, the described embodiments are some, but not all, of the embodiments of the disclosure. And the embodiments and features in the embodiments of the disclosure may be combined with each other without conflict. Based on the described embodiments of the disclosure, all other embodiments obtained by those of ordinary skill in the art without creative efforts fall within the scope of the disclosure.

Unless otherwise defined, technical terms or scientific terms used in this disclosure shall have the usual meaning understood by a person with ordinary skill in the art to which this disclosure belongs. Words such as “First”, “second” used in the disclosure do not indicate any order, quantity or importance, but are only used to distinguish different components. Words such as “including” or “comprising” refer to the components or objects that appear before the word, including those listed after the word and their equivalents, without excluding other components or objects. Words such as “connected” or “connecting” are not limited to physical or mechanical connections, but may include electrical connections, whether direct or indirect.

It should be noted that the sizes and shapes of the figures in the drawings do not reflect true proportions and are only intended to illustrate the disclosure. And, the same or similar reference numbers throughout represent the same or similar components or elements having the same or similar functions.

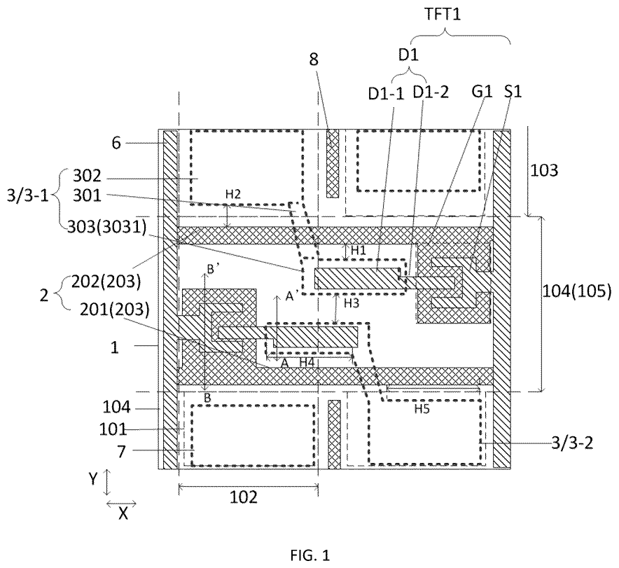

Embodiments of the disclosure provide an array substrate, as shown in FIG. 1, the array substrate includes: a base substrate 1, including a plurality of sub-pixel areas 101 arranged in an array, and a first area 104 between adjacent sub-pixel areas 101; a plurality of scanning lines 2, on a side of the base substrate 1 and in the first area 104; where the plurality of scanning lines 2 extend in a first direction X, and are arranged in a second direction Y, the first direction X intersects with the second direction Y; a plurality of first pixel electrodes 3, on a side of the scanning lines 2 facing away from the base substrate 1; where the plurality of first pixel electrodes 3 each include: a first portion 301; and a second portion 302 and a third portion 303 at both sides of the first portion 301 in the second direction Y; an orthographic projection of the first portion 301 on the base substrate 1 and an orthographic projection of the scanning line 2 on the base substrate 1 have an overlapping area; an orthographic projection of the second portion 302 on the base substrate 1 and an orthographic projection of the third portion 303 on the base substrate 1 are arranged at two sides of the scanning line 2, respectively.

The array substrate provided by embodiments of the disclosure includes a first pixel electrode, the first pixel electrode includes a first portion whose orthographic projection of the first portion on the base substrate overlapping the orthographic projection of the scanning line on the base substrate, and the first pixel electrode further includes a second portion and a third portion arranged at two sides of the scanning line. When both the second portion and the third portion have parasitic capacitance with the scanning line, if there is an offset of all the first pixel electrodes included in the array substrate in the second direction due to a process deviation, compared to the case in which there is no offset, since the second portion and the third portion are respectively arranged at two sides of the scanning line, the parasitic capacitance of one of the second portion and the third portion with the scanning line increases, while the parasitic capacitance of the other one of the second portion and the third portion with the scanning line decreases. Due to the same offset, the absolute value of the change in parasitic capacitance between the second portion and the scanning line and the absolute value of the change in parasitic capacitance between the third portion and the scanning line are the same, that is, the change in parasitic capacitance between the second portion and the scanning line as well as the change in parasitic capacitance between the third portion and the scanning line are complementary. Even if the position of the first pixel electrode is offset due to process deviation, the parasitic capacitance between each first pixel electrode and the scanning line is still equal, avoiding significant differences in the charging rate of different pixel electrodes caused by different parasitic capacitances between the first pixel electrodes and the scanning line. When the array substrate is applied to display products, it can avoid differences in brightness between different sub-pixel areas. When users move to view display products, increase of difference in brightness can be avoided, thereby avoiding shake-head stripe, improving display performance, and enhancing user experience.

It should be noted that only part of the array substrate area is shown in FIG. 1, and taking the first direction X and the second direction Y perpendicular as an example in FIG. 1 for illustration.

In some embodiments, as shown in FIG. 1, the orthographic projection of the second portion 302 on the base substrate 1 and the sub-pixel area 101 have an overlapping area, and the orthographic projection of the third portion 303 on the base substrate 1 is located within the first area 104.

In some embodiments, as shown in FIG. 1, the plurality of sub-pixel areas 101 are divided into multiple sub-pixel area columns 102 and multiple sub-pixel area rows 103, and the multiple sub-pixel area columns 102 extend in the second direction Y and are arranged in the first direction X; the multiline sub-pixel area rows 103 are arranged in the second direction Y and extend in the first direction X.

In some embodiments, as shown in FIG. 1, a plurality of scanning lines 2 include a plurality of first scanning lines 201 and a plurality of second scanning lines 202. The first scanning line 201 and the second scanning line 202 are alternately arranged. One first scanning line 201 and one second scanning line 202 are arranged between every two adjacent sub-pixel areas 101 in the second direction Y.

In specific implementation, each sub-pixel area row corresponds to one first scanning line and one second scanning line arranged respectively at two sides of the each sub-pixel area row.

That is, the scanning lines of the array substrate provided in the embodiment of the disclosure are of dual gate design.

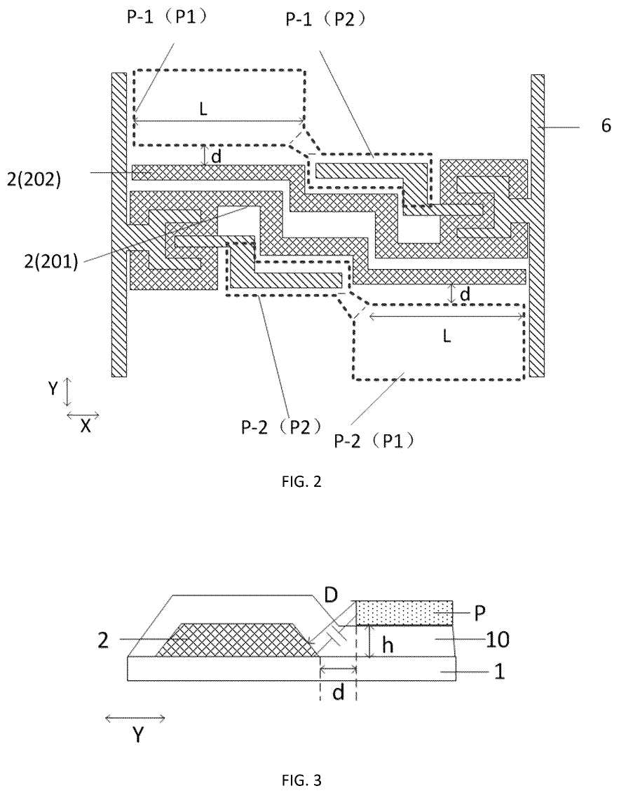

It should be noted that the structure of the array substrate in the related technology is as shown in FIG. 2. The orthographic projection of the pixel electrode P of the array substrate on the base substrate and the orthographic projection of the scanning line 2 on the base substrate do not overlap each other. In the second direction, the pixel electrode P1 is located at one side of the scanning line 2 corresponding to the pixel electrode P1. The schematic diagram of parasitic capacitance generated between the pixel electrode P and the scanning line 2 is shown in FIG. 3. When calculating the parasitic capacitance, C=ε*S/D, E is a constant. According to the Pythagorean theorem, D=(d²+h²)^{1/2}, d is the distance between the pixel electrode and the scanning line in the second direction, h is the distance between the plane where the pixel electrode is located and the plane where the scanning line is located, D is the distance between the side surface of the scanning line and the side surface of the pixel electrode. In the actual product, d=5 um, h=0.35 um. Since h is very small compared with d, D=d. When calculating the parasitic capacitance, the overlapping area of parasitic capacitance S=THK*L, and the calculation formula of parasitic capacitance C is C=ε*THK*L/d, where L is the length of the facing area between the pixel electrode and the scanning line, and THK is the thickness between the scanning line and the pixel electrode corresponding to the facing area. In FIG. 2, capacitances are formed between the second area P1 and the third area P2 of the pixel electrode P with the scanning line 2. When the pixel electrodes do not shift, the widths of the area where the capacitance is generated between the second region P1 and the scanning line 2, as well as the area where the capacitance is generated between the third region P2 and the scanning line 2, are L; the distance between the second region P1 and the scanning line 2, as well as the distance between the third region P2 and the scanning line 2, are d; and the parasitic capacitance between the pixel electrode P and the scanning line 2 in FIG. 2 is ε*THK*2L/d. When pixel electrode P is shifted upwards by ΔD, the parasitic capacitance between the pixel electrode P-2 corresponding to the first scanning line 201 and the scanning line becomes ε*THK*2L/(d−Δd), and the parasitic capacitance between the pixel electrode P-1 corresponding to the second scanning line 202 and the scanning line becomes ε*THK*2L/(d+Δd). There is a difference in the parasitic capacitance of the pixel electrode P corresponding to two scanning lines. When the array substrate is applied to a display product, and the display product uses column flipping to drive pixels, parasitic capacitance will cause obvious periodic vertical stripes of bright-bright-dark-dark arrangement for a single frame display. After the polarity of the frame is reversed, the bright and dark will be reversed and become dark-dark-bright-bright arrangement, so as to achieve uniform bright and dark in time. However, when a user moves to see the screen, such as shaking their head to view the screen of a display product, a certain positive or negative frame may be lost, which cannot make uniform bright and dark in time, resulting in poor shake-head stripe. However, in the array substrate provided by embodiments of the disclosure, since the second portion and the third portion are located at two sides of the scanning line, when the width of the area where the capacitance is generated between the second portion and the scanning line and the width of the area where the capacitance is generated between the third portion and the scanning line are both L, and in a case of no shift, the distance between the second portion and the scanning line and the distance between the third portion and the scanning line are both d, the parasitic capacitance of the first pixel electrode provided by the embodiment of the disclosure is: ε*THK*2L/d. When the first pixel electrode P provided by the embodiment of the disclosure is offset upwards by Δd, in the first pixel electrode corresponding to the first scanning line, the parasitic capacitance corresponding to the third portion is ε*THK*L/(d+Δd), the parasitic capacitance corresponding to the second portion is ε*THK*L/(d−Δd), the parasitic capacitance corresponding to the first pixel electrode is ε*THK*L/(d+Δd)+ε*THK*L/(d−Δd). In the first pixel electrode corresponding to the second scanning line, the parasitic capacitance corresponding to the third portion is ε*THK*L/(d)−Δd), the parasitic capacitance corresponding to the second portion is ε*THK*L/(d)+Δd), and the parasitic capacitance corresponding to the first pixel electrode is ε*THK*L/(d+Δd)+ε*THK*L/(d−Δd). That is to say, even if the first pixel electrode is offset due to process errors and other factors, the parasitic capacitance between each first pixel electrode and the scanning line is still equal, so as to avoid significant differences in charging rates between different first pixel electrodes and scanning lines, and thus avoiding differences in brightness between different sub-pixel areas. When the user moves to watch, it can avoid aggravating the brightness difference, avoiding shake-head stripe, improving the display effect and the user experience.

In some embodiments, as shown in FIG. 1, the array substrate further includes:
a plurality of data lines 6 in the first area 104 and between the scanning line 2 and the first pixel electrode 3 in a direction perpendicular to the base substrate 1; where the plurality of data lines 6 extend in the second direction Y and are arranged in the first direction X, and there are two sub-pixel area columns 102 located between every two adjacent data lines 6;
a plurality of thin-film transistors in the first area 104 and at the same side of the base substrate 1 as the scanning line 2; where the plurality of thin-film transistors include a plurality of first thin-film transistors TFT1, and the first thin-film transistor TFT1 includes a first electrode G1, a second electrode S1, and a third electrode D1; the first electrode G1 is electrically connected with the scanning line 2, the second electrode S1 is electrically connected with the data line 6, and the third electrode D1 is electrically connected with the first pixel electrode 3.

In a specific implementation, for example, the first electrode is the gate electrode of the first thin-film transistor, the second electrode is the source electrode of the first thin-film transistor, and the third electrode is the drain electrode of the first thin-film transistor.

In some embodiments, as shown in FIG. 1, in the first area 104 between two adjacent sub-pixel area rows 103, the data line 6 between two adjacent sub-pixel area columns 102 is electrically connected with two thin-film transistors, and the two thin-film transistors TFT are respectively located at two sides of the data line 6 in the first direction X.

In the array substrate provided by embodiments of the disclosure, since the scanning lines are designed as Dual Gate, one data line can drive multiple sub-pixel area columns, which can reduce the number of data lines and reduce the cost.

In some embodiments, the first electrode and the scanning line are provided in the same layer; and the first electrode and the scanning line can be electrically connected and integrally arranged. The second electrode, the third electrode, and the data line are provided in the same layer, and the second electrode and the data line can be electrically connected and integrally arranged.

In some embodiments, as shown in FIG. 1, in the second direction Y, the first thin-film transistor TFT1 and the third portion 303 are arranged at the same side of the scanning line 2 electrically connected with the first thin-film transistor TFT1. The orthographic projection of the third portion 303 on the base substrate 1 and the orthographic projection of the third electrode D1 on the base substrate 1 have an overlapping area, and the third portion 303 is electrically connected with the third electrode D1.

In the array substrate provided in embodiments of the disclosure, since the first pixel electrode includes the second portion and the third portion arranged at two sides of the scanning line respectively in the second direction, and the third portion is arranged in the first area and the second portion is arranged in the sub-pixel area, the first thin-film transistor and the third portion are arranged at the same side of the scanning line, so that the third electrode is electrically connected with the third portion, thereby facilitating the realization of the electrical connection between the third electrode and the first pixel electrode, and further rationally utilizing the space in the first area.

In some embodiments, as shown in FIG. 1, the third electrode D1 includes a first strip portion D1-1 extending in the first direction X, the third portion 303 includes a second strip portion 3031 extending in the first direction X; and the orthographic projection of the second strip portion 3031 on the base substrate 1 and the orthographic projection of the first strip portion D1-1 on the base substrate 1 have an overlapping area.

In specific implementation, the first pixel electrode is arranged at the side of the third electrode facing away from the base substrate, and instead of providing an insulation layer between the first pixel electrode and the third electrode, the first pixel electrode and the third electrode are in direct contact to realize an electrical connection. In the array substrate provided by embodiments of the disclosure, the orthographic projection of the second strip portion on the base substrate and the orthographic projection of the first strip portion on the base substrate have an overlapping area, so that the first pixel electrode and the third electrode can be lapped to realize the electrical connection.

In some embodiments, as shown in FIG. 1, the orthographic projection of the second strip portion 3031 on the base substrate 1 covers the orthographic projection of the first strip portion D1-1 on the base substrate 1. Thus, the contact area between the second strip portion and the first strip portion can be increased, and the electrical connection performance between the first pixel electrode and the third electrode can be improved.

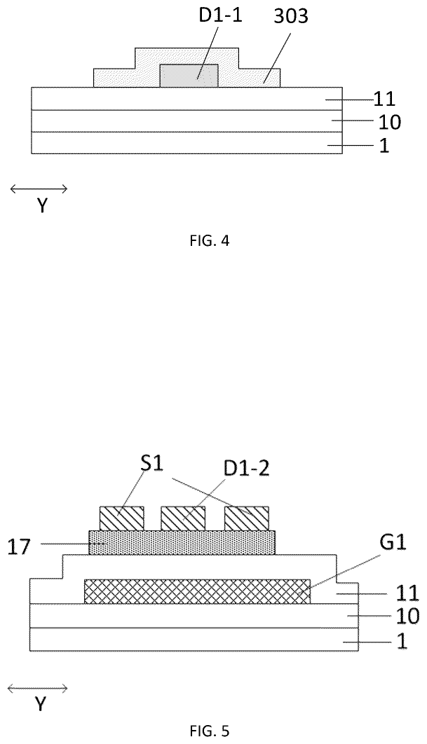

In specific implementation, as shown in FIG. 4, in the second direction Y, the width of the orthographic projection of the second strip portion 3031 on the base substrate 1 is greater than the width of the orthographic projection of the first strip portion D1-1 on the base substrate 1, and the orthographic projection of the second strip portion 3031 on the base substrate 1 covers the edge of the orthographic projection of the first strip portion D1-1 on the base substrate 1.

In some embodiments, as shown in FIG. 4, the second strip portion 3031 covers the side surface of the first strip portion D1-1. Thus, the contact area between the second strip portion and the first strip portion can be further increased, and the electrical connection performance between the first pixel electrode and the third electrode can be improved.

It should be noted that, FIG. 4 is the cross-sectional view along AA′ in FIG. 1. As shown in FIG. 4, the array substrate further includes a buffer layer 10 and a gate insulation layer 11. Where, the buffer layer is arranged between the base substrate and the first electrode.

In specific implementations, the thin-film transistor further includes an active layer. The thin-film transistor can be a top-gate structure, a bottom-gate structure, and so on. When the thin-film transistor is the top-gate structure, the gate insulation layer is arranged between the buffer layer and the first electrode, the active layer is arranged between the buffer layer and the gate insulation layer, and the array substrate further includes an interlayer insulation layer between the first electrode and the layer where the second electrode and drain electrode are located. When the thin-film transistor is a bottom-gate structure, the active layer is arranged at the side of the first electrode facing away from the buffer layer, and the gate insulation layer is arranged between the active layer and the first electrode.

In some embodiments, as shown in FIG. 1, the orthographic projection of the third portion 303 on the base substrate 1 does not overlap with the orthographic projection of the first electrode G1 on the base substrate 1. Accordingly, the orthographic projection of the first strip portion D1-1 on the base substrate 1 and the orthographic projection of the first electrode G1 on the base substrate 1 do not overlap each other.

It should be noted that, in FIG. 1, the third portion 303 only includes the second strip portion 3031. The third electrode D1 further includes a fourth strip portion D1-2 connected with the first strip portion D1-1.

In some embodiments, as shown in FIG. 1, the orthographic projection of the second electrode S1 on the base substrate 1 and the orthographic projection of the first electrode G1 on the base substrate 1 have an overlapping area, and the orthographic projections of the two have the overlapping area, and the pattern of the orthographic projection of the second electrode S1 on the base substrate 1 has a concave area. The orthographic projection of the fourth strip portion D1-2 on the base substrate 1 and the orthographic projection of the first electrode G1 on the base substrate 1 have an overlapping area. The fourth strip portion D1-2 extends to the concave area of the second electrode S1 so that the channel area between the second electrode S1 and the fourth strip portion D1-2 is U-shaped. The cross-sectional view along BB′ in FIG. 1 is shown in FIG. 5.

In specific implementation, the width of the first strip portion is greater than the width of the fourth strip portion in the second direction. That is, the width of the portion outside the first electrode is increased in the second direction, so that the contact area between the third electrode and the first pixel electrode can be increased.

In some embodiments, as shown in FIG. 1, the first thin-film transistor TFT1 and the first pixel electrode 3 electrically connected with the first thin-film transistor TFT1 are located between two adjacent data lines 6.

Since the array substrate provided by embodiment of the disclosure adopts the dual gate design, there is no need to arrange date the line in a part of gaps between two adjacent sub-pixel area columns, and thus there is no need to arrange the thin-film transistor in the first area, that is, the wiring space in the first area between two adjacent data lines is large, which means that the wiring space between the third portion and the first thin-film transistor is sufficient in this area, which is convenient for production.

In some embodiments, as shown in FIG. 1, in the first direction X, the second portion 302 and the third portion 303 are respectively arranged at two sides of the first portion 301.

In some embodiments, as shown in FIG. 1, the orthographic projection of the first strip portion D1-1 on the base substrate 1 passes through the area between two adjacent sub-pixel area columns 102;
in the first pixel electrode 3 and the first thin-film transistor TFT1 electrically connected with each other, the first electrode G1 and the second portion 302 respectively correspond to two adjacent different sub-pixel area columns 102.

In the array substrate provided by embodiments of the disclosure, since each sub-pixel area row corresponds to the first scanning line and the second scanning line, when two adjacent sub-pixel areas in each sub-pixel area row are driven by the first scanning line and the second scanning line, respectively, there exists a case in which these two sub-pixel areas are electrically connected with different scanning lines, and there exists a case in which a thin-film transistor and a sub-pixel area corresponding to the thin-film transistor are arranged in different columns, where the thin-film transistor is the first thin-film transistor. Accordingly, the first thin-film transistor and the second portion of the first pixel electrode are located in different columns. Since the third portion of the first pixel electrode is electrically connected with the third electrode, the second portion and the third portion of the first pixel electrode are located at two sides of the first portion in the first direction, thereby facilitating the first thin-film transistor and the second portion being located in different columns in the case where the third electrode is electrically connected with the third portion.

In some embodiments, as shown in FIG. 1, between two adjacent date lines 6, the two first pixel electrodes 3 respectively corresponding to the first scanning line 201 and the second scanning line 202, in the first area 104 adjacent to each other, are located in different sub-pixel area columns 102.

In some embodiments, as shown in FIG. 1, between two adjacent data lines 6 and in the first area 104 corresponding to the first thin-film transistor TFT1, the scanning line 2 includes a third strip portion 203 extending in the first direction X; that is, the edge of the third portion close to the third strip portion 203 is parallel to the third strip portion 203;
an edge of the second portion 302 close to the third strip portion 203 is parallel to the third strip portion 203.

That is, the edge of the third portion close to the third strip portion and the edge of the second portion close to the third strip portion are both parallel to the third strip portion.

In the wiring substrate provided in embodiments of the disclosure, since the first pixel electrode includes the second portion and the third portion arranged at two sides of a scanning line, and the first thin-film transistor and the third portion are arranged at the same side of the scanning line, the first area between two adjacent data lines and corresponding to the first thin film transistor is also the area where the third portion is arranged; and the scanning line in this area includes the third strip portion, so that scanning line in this area occupies less space and there is more wiring space in the first area for the third portion and the third electrode of the first thin-film transistor, which is convenient for production.

In some embodiments, as shown in FIG. 1, in the second direction Y, the distance H2 between the third portion 303 and the scanning line 2 and the distance H1 between the second portion 302 and the scanning line 2 are approximately equal.

It should be noted that, the distance between the third portion and the scanning line is approximately equal the distance between the second portion of the scanning line, meaning that the distance between the third part and the scanning line, and the distance between the second part and the scanning line, whose difference therebetween is within the range of process error, can be regarded as that the distance between the third part and the scanning line, and the distance between the second part and the scanning line is equal.

In some embodiments, as shown in FIG. 1, the edge of the first electrode G1 close to the third portion 303 is perpendicular to the third strip portion 203.

In specific implementation, as shown in FIG. 1, the shape of the orthographic projection of the first electrode G1 on the base substrate is approximately rectangular.

In some embodiments, as shown in FIG. 1, between two adjacent data lines 6, and between two adjacent sub-pixel area rows 103, two first electrodes G1 electrically connected with the respective first scanning line 201 and the second scanning line 202 are opposite to each other in the first direction X, and the orthographic projections of the first strip portion D1-1 and the second strip portion 3031 on the base substrate 1 are arranged between the orthographic projections the two first electrodes G1 on the base substrate 1.

In a specific implementation, since the edge of the first electrode close to the third portion is perpendicular to the third strip portion, the opposite sides of the two first electrodes arranged opposite to each other are parallel to each other.

In a specific implementation, when a thin-film transistor is to be provided in an area between two adjacent data lines and between two adjacent sub-pixel area rows, the two thin-film transistors in the area are both first thin-film transistors. In this area, two first strip portions and two second strip portions should be provided between two first electrodes and between two third strip portions, two first electrodes are provided opposite to each other and the opposite sides of the two first electrodes are parallel to each other. The third strip portion of the first scanning line and the third strip portion of the second scanning line are provided opposite to each other. The area surrounded by the two first electrodes as well as the two third strip portions includes a rectangular area, which provides sufficient wiring space for the two first strip portions and the two second strip portions, reducing the difficulty of production.

In specific implementation, H1 and H2 are greater than or equal to 5 micrometers and less than or equal to 7 micrometers, for example, H1 and H2 both can be 6 micrometers. Between two adjacent sub-pixel area rows, the distance H3 between two adjacent third portions in the second direction is greater than or equal to 7.2 micrometers and less than or equal to 9.2 micrometers, for example, H3 is 8.2 micrometers. In some embodiments, the width H4 of the area facing the scanning line in the second portion is approximately equal to the width H5 of the area facing the scanning line in the third portion. H4 and H5 are greater than or equal to 49 micrometers and less than or equal to 51 micrometers, for example, H4 and H5 both are 50 micrometers.

It should be noted that, in FIG. 1, taking the area enclosed by two first electrodes and two third strip portions, including a rectangular area, as an example for explanation, in the area, the line width of the scanning line is the line width of the third strip portion, and the line width of the third strip portion is uniform. Of course, in specific implementation, it is also possible to increase the line width of the scanning line on the basis of the third strip portion in the area where the third portion is not provided, in order to reduce the resistance of the scanning line and reduce the impedance of the scanning line.

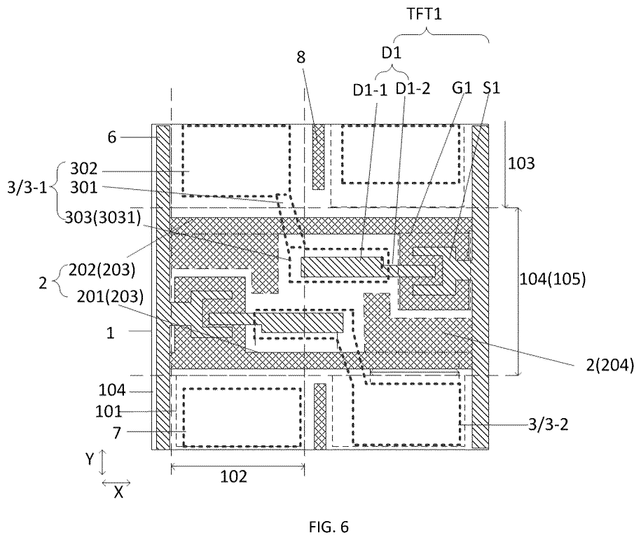

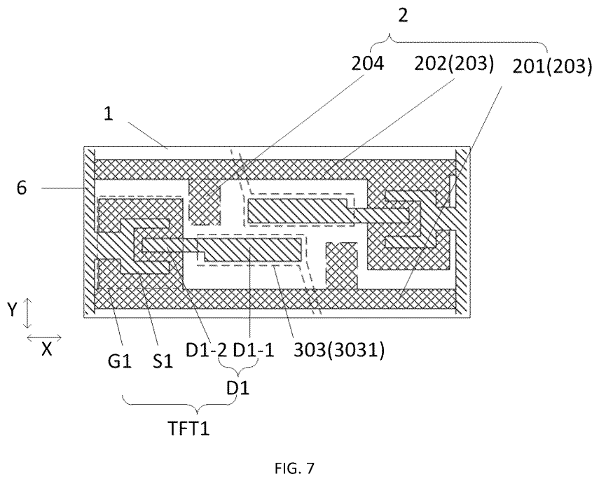

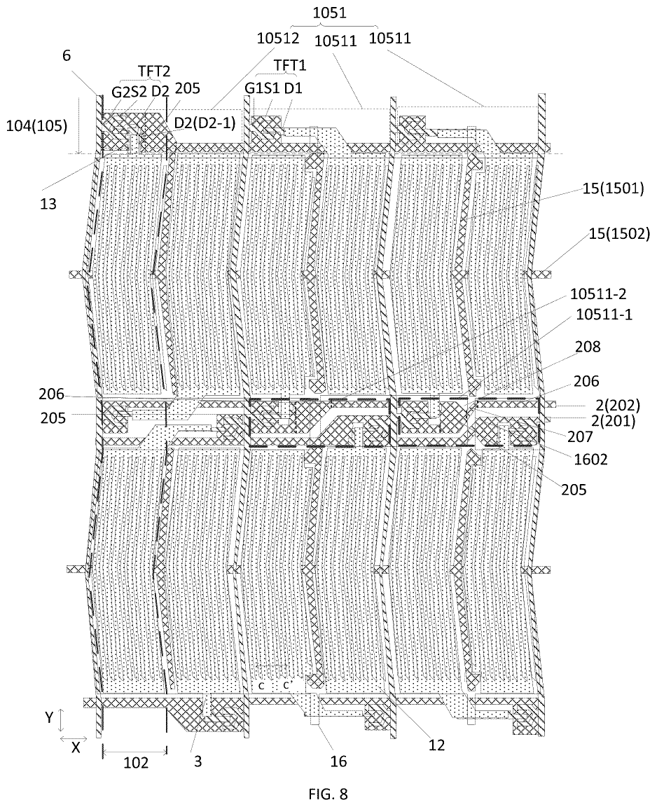

In some embodiments, as shown in FIGS. 6 and 7, the scanning line 2 further includes: a first widening portion 204 connected with the third strip portion 203 in the second direction Y; the first widening portion 204 and the third portion 303 are arranged at the same side of the third strip portion 203.

In the array substrate provided by embodiments of the disclosure, the scanning line further includes a first widening portion at one side of the third strip portion, which is equivalent to increasing the line width of the scanning line in a corresponding area of the third strip portion, so that the resistance of the scanning line can be reduced and the impedance of the scanning line can be reduced.

In some embodiments, as shown in FIG. 6 and FIG. 7, in the first direction X, the orthographic projection of the first widening portion 204 on the base substrate 1 and the orthographic projection of the first electrode G1 on the base substrate 1 are arranged at two sides of the orthographic projection of the first strip portion D1-1 on the base substrate 1. The orthographic projection of the first widening portion 204 on the base substrate 1 does not overlap with the orthographic projection of the first pixel electrode 3 on the base substrate 1. That is, the line width of the scanning line is increased in the area other than that corresponding to the third portion of the first pixel electrode.

In some embodiments, if the distance between the third strip portion and the first electrode adjacent to the third strip portion is large, as shown in FIG. 6, the orthographic projection of the first widening portion 204 on the base substrate 1 includes: a portion between the orthographic projections of the two first electrodes G1 opposite to each other on the base substrate 1, and a portion between the orthographic projection of the first electrode G1 on the base substrate 1 and the orthographic projection of the third strip portion 203 on the base substrate 1 in the second direction Y.

Or, if the distance between the third strip portion and the first electrode adjacent to the third strip portion is small, in some embodiments, as shown in FIG. 7, between two adjacent data lines 6, and between two adjacent sub-pixel area rows 103, the orthographic projection of the first widening portion 204 on the base substrate 1 is arranged between the orthographic projections of the two first electrodes G1 which are opposite to each other.

In some embodiments, as shown in FIG. 8, the array substrate further includes:
a plurality of second thin-film transistors TFT2; where the second thin-film transistor TFT2 includes a fourth electrode G2, a fifth electrode S2 and a sixth electrode D2. In the first direction X, the length of the sixth electrode D2 is less than the length of the third electrode D1; the fourth electrode G2 is electrically connected with the scanning line 2, and the fifth electrode S2 is electrically connected with the data line 6;
a plurality of second pixel electrodes 12, which are arranged in the same layer as the first pixel electrode 3; the orthographic projection of the second pixel electrode 12 on the base substrate 1 does not overlap with the orthographic projection of the scanning line 2 on the base substrate 1; the second pixel electrode 12 is electrically connected with the sixth electrode D2;
the second pixel electrode 12 and the second thin-film transistor TFT2 electrically connected with the second pixel electrode 12 correspond to a same one sub-pixel area column 102.

In a specific implementation, for example, the fourth electrode is the gate electrode of the second thin-film transistor, the fifth electrode is the source electrode of the second thin-film transistor, and the sixth electrode is the drain electrode of the second thin-film transistor.

In a specific implementation, the total number of the first thin-film transistors and the second thin-film transistors is equal to the number of sub-pixel areas, each sub-pixel area corresponds to a first thin-film transistor or a second thin-film transistor, and the total number of the first pixel electrodes and the second pixel electrodes is equal to the number of sub-pixel areas, each sub-pixel area corresponds to a first pixel electrode or a second pixel electrode.

It should be noted that, since the second pixel electrode and the second thin-film transistor are located in the same column, the second pixel electrode does not need to cross the area corresponding to the two sub-pixel area columns, the size of the area of the second pixel electrode facing the scanning line is smaller than the size of the area of the first pixel electrode facing the scanning line, thus the parasitic capacitance between the second pixel electrode and the scanning line is small, which has a smaller impact on the display effect. Therefore, in the array substrate provided by embodiments of the disclosure, the second pixel electrode does not need to cross the scanning line, which can reduce the wiring difficulty of the array substrate as well as the production difficulty.

In some embodiments, as shown in FIG. 8, between two adjacent data lines 6 and in the first area 104 corresponding to the second thin-film transistor TFT2, the pattern of the orthographic projection of the fourth electrode G2 on the base substrate 1 has a first concave area 13, the orthographic projection of the sixth electrode D2 on the base substrate 1 and the first concave area 13 have an overlapping area, and the sixth electrode D2 and the second pixel electrode 12 are electrically connected in the first concave area 13.

In some embodiments, as shown in FIG. 8, between two adjacent data lines 6, and in the first area 104 corresponding to the second thin-film transistor TFT2, the scanning line includes a second widening portion 205, and a fourth strip portion 206 extending in the first direction; the fourth electrode G2 and the second widening portion 205 are respectively located at two sides of the first concave area 13 in the first direction X, and the fourth strip portion 206 is arranged at the side of the second widening portion 205 facing away from the first concave area 13;
in the second direction Y, the width of the second widening portion 205 is greater than the width of the fourth strip portion 206.

In a specific implementation, when the array substrate is applied to a display product, it can be used as the array substrate of a liquid crystal cell, the liquid crystal cell further includes an opposing substrate arranged opposite to the array substrate, the alignment films are required to be arranged on the opposite sides of the array substrate and the opposing substrate. The opposing substrate includes a plurality of spacers whose orthographic projections is within the orthographic projection of the second widening portion. Since the width of the second widening portion of the scanning line in the second direction is greater than the width of the strip portion extending in the second direction, meaning that the line width of the scanning line at the second widening portion of the scanning line is widened. When the array substrate is applied to the liquid crystal cell, the second widening portion of the scanning line can be used to support the spacers, which can prevent scratches on the alignment film caused by the sliding of the spacer when the liquid crystal cell product is subjected to force deformation.

In some embodiments, when the array substrate is applied to liquid crystal display products, the orthographic projection of the spacer, included in the liquid crystal display product, on the base substrate is circular, with a diameter greater than or equal to 15 micrometers and less than or equal to 17 micrometers, for example, the diameter is 16 micrometers. Correspondingly, the width of the second widening portion in the first direction is greater than or equal to 35 micrometers and less than or equal to 36 micrometers, for example, the width of the second widening portion in the first direction is 35 micrometers; the width of the second widening portion in the second direction is greater than or equal to 29 micrometers and less than or equal to 31 micrometers, for example, the width of the second widening portion in the second direction is 30 micrometers.

In some embodiments, in the second direction, the maximum width of the second widening portion is equal to the width of the fourth electrode.

In some embodiments, as shown in FIG. 8, the array substrate further includes: a common electrode 16 and a common electrode line 15 electrically connected with the common electrode 16. For example, the common electrode is arranged at a side of the first pixel electrode facing away from the base substrate. The common electrode line is arranged in the same layer as the scanning line.

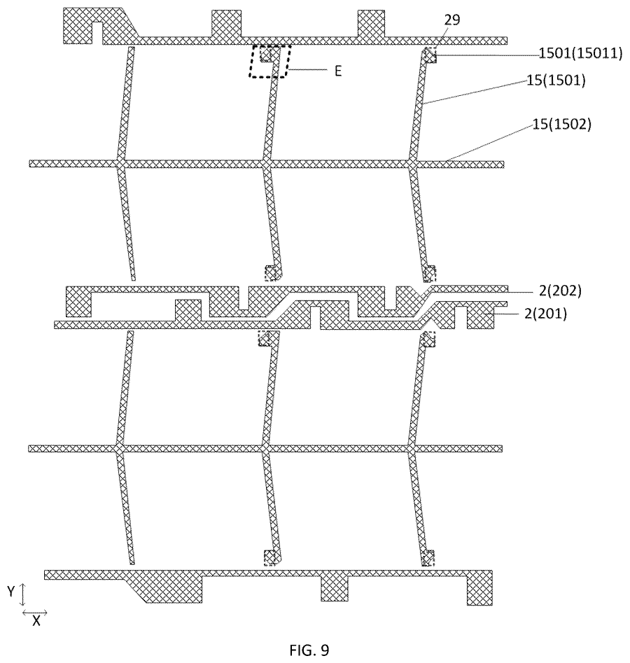

In specific implementation, as shown in FIG. 9, the common electrode line 15 includes a second common electrode line 1502 extending in the first direction X and a first common electrode line 1501 extending in the second direction. The first common electrode line 1501 is arranged between two adjacent sub-pixel areas (not shown) in the first direction X. The orthographic projection of the second common electrode line 1502 on the base substrate 1 and the sub-pixel area 101 have an overlapping area. For example, in the second direction, the distances between the second common electrode line and the edges of the sub-pixel areas at two sides of the second common electrode line are approximately equal.

It should be noted that, the distance between the second common electrode line and the edges of the sub-pixel area at two sides of the second common electrode line are approximately equal, meaning that the distances between the second common electrode line and the edges of the sub-pixel area at two sides of the second common electrode line, with a difference being within a range of the process error, can be regarded as the distances between the second common electrode line and the edges of the sub pixel area at two sides of the second common electrode line are equal.

It should be noted that, the distance between the second common electrode line and the edges of the sub-pixel area at two sides of the second common electrode line are approximately equal, that is, the second common electrode line approximately passes through the center of the sub-pixel area. When the array substrate is applied to a liquid crystal display product, the area in which the second common electrode line is arranged corresponds to the weak light effect area of the liquid crystal, meaning that the second common electrode line has less effect on the opening rate of the sub-pixel. Therefore, the second common electrode line does not need to be arranged in the area between the two scanning lines in the first area. It can reduce the size of the first area in the second direction, increase the area of the sub pixel area, and thus improve the opening rate of the sub-pixel.

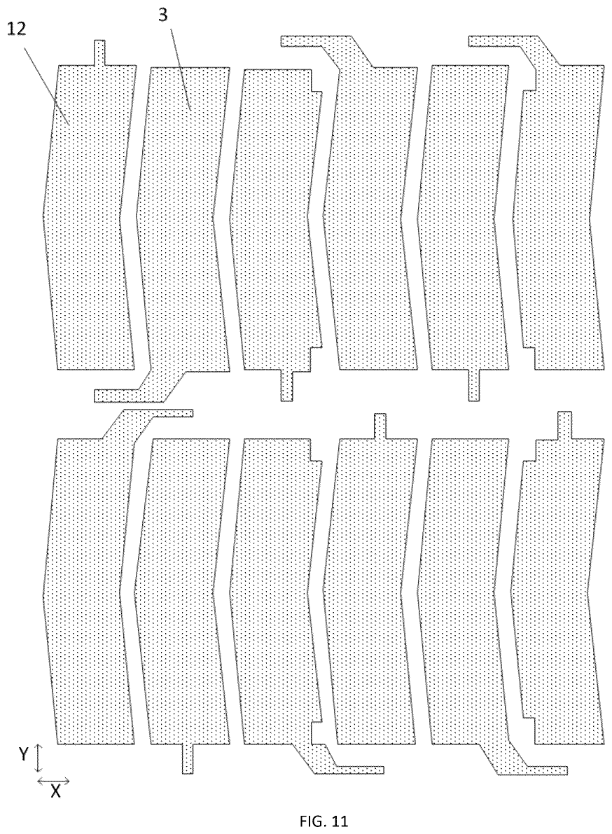

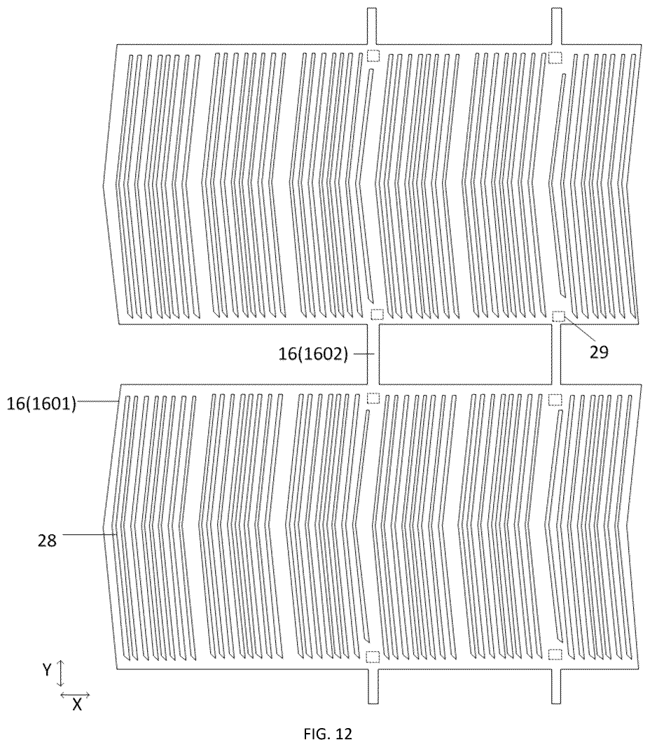

In some embodiments, as shown in FIG. 12, the common electrode 16 includes: a plurality of sub-common electrodes 1601, and a plurality of first connection portions 1602;
the sub-commons electrode 1601 correspond to the sub-pixel area row, the first connection portion 1602 extends in the second direction, and the first connection portion 1602 is electrically connected with the sub-commons electrode 1601.

In a specific implementation, as shown in FIG. 8, the orthographic projection of the first connection portion 1602 on the base substrate 1 and the orthographic projection of the scanning line 2 on the base substrate have an overlapping area.

In some embodiments, as shown in FIG. 8, between two adjacent data lines 6, and in the first areas 104 corresponding to at least part of the second thin-film transistors TFT2, the scanning line 2 further includes: a fifth strip portion 207 connecting the second widening section 205 and the fourth strip portion 206;
an angle between an extension direction of the fifth strip portion 207 and the first direction X is greater than 0, and an angle between the extension direction of the fifth strip portion 207 and the second direction Y is greater than 0;
a pattern formed by an orthographic projection of the second widening portion 205 on the base substrate and an orthographic projection of the fifth strip portion 207 on the base substrate has a second concave area 208;
an orthographic projection of the second concave area 208 on the base substrate and the orthographic projection of the fifth strip portion 207 on the base substrate overlap with an area between two adjacent sub-pixel area columns.

It is to be noted that the first concave area and the second concave area involved in embodiments of the disclosure can be understood as that the planar graphic of the orthographic projection the scanning line on the base substrate has a notch.

In some embodiments, as shown in FIG. 8, the orthographic projection of at least part of the first connection portions 1602 on the base substrate and the orthographic projection of the second concave area 208 on the base substrate have an overlapping area, and the orthographic projection of the at least part of the first connection portions 1602 on the base substrate and the orthographic projection of the fifth strip portion 207 on the base substrate have an overlapping area.

In the array substrate provided by embodiments of the disclosure, a pattern of the scanning line has a second concave area, and the orthographic projection of the first connection portions on the base substrate corresponds to an area of the scanning line corresponding to the fifth strip portion. In this area, since the pattern of the scanning line has the second concave area, the overlapping area between the orthographic projection of the first connection portion and the orthographic projection of the scanning line is relatively small in size, which can reduce the parasitic capacitance between the first connection portion and the scanning line.

In a specific implementation, in an area between two adjacent sub-pixel opening rows, and in an area between two adjacent data lines, the fifth strip portions of the adjacent first scanning line and second scanning line are parallel to each other, so that in the case that the scanning line has the second widening portion, the space in the first area can be effectively utilized. It is also possible to make the first connection portion overlap evenly with the first scanning line and the second scanning line to avoid differences in parasitic capacitance.

In some embodiments, as shown in FIG. 8, between two adjacent data lines 6, and in the first area 104 corresponding to at least part of the second thin-film transistors TFT2, the second widening section 205 is connected with the fourth strip portion 206.

In some embodiments, when the second widening portion is directly connected with the fourth strip portion, at a side of the scanning line close to the sub-pixel area, the edge of the second widening portion and the edge of the fourth strip portion are located in the same straight line. That is, at the side of the scanning line close to the sub-pixel area, the pattern of the second widening portion and the pattern of the fourth strip portion do not have a concave area.

That is, in the array substrate provided in embodiments of the disclosure, in the first area corresponding to a part of the second thin-film transistors, the pattern of the scanning line has a second concave area, while in the first area corresponding to the other part of the second thin-film transistors, the pattern of the scanning line does not have a second concave area. For example, in FIG. 8, the pattern of the scanning line in the area indicated by 10511-1 in the figure has a second concave area, while the pattern of the scanning line in the area indicated by 10511-2 in the figure does not have a second concave area.

In specific implementation, if the patterns of the scanning lines in the first areas corresponding to the second thin-film transistors all have the second concave area, and the line width of the scanning lines in the first area corresponding to the first thin-film transistor is narrower, this will cause an increase in the resistance and impedance of the scanning line. In the array substrate provided by embodiments of the disclosure, the patterns of the scanning lines in some areas do not have the second concave area, which can compensate for the overall resistance of the scanning line. This can avoid shake-head stripe caused by deviation in the first pixel electrode size, reduce parasitic capacitance between the scanning line and the common electrode, and avoid excessive increase in the resistance of the scanning line.

In some embodiments, as shown in FIG. 8, the orthographic projection of at least part of the first connection portion 1602 on the base substrate and the orthographic projection of the second widening portion 205 on the base substrate have an overlapping area.

In a specific implementation, when the second widening portion is directly connected with the fourth strip portion, the orthographic projection of the second widening portion on the base substrate is trapezoid shaped. In an area between two adjacent sub-pixel opening rows and between two adjacent data lines, the opposite edges of the second widening portions of the adjacent first scanning line and second scanning line are lateral sides of the trapezoids. In this case, the opposite edges of the second widening portions of the adjacent first scanning line and second scanning line are parallel to each other, so that in the case of the scanning line having the second widening portion, the space of the first area may be efficiently utilized. It is also possible to make the first connection portion overlap evenly with the first scanning line and the second scanning line to avoid differences in parasitic capacitance.

In some embodiments, as shown in FIG. 9, at least part of the first common electrode line 1501 includes: a second connection portion 15011. The second connection portion 15011 is located at one end of the first common electrode line 1501 in the extension direction. The width of the second connection portion 15011 in the first direction X is greater than the width of the rest of the first common electrode line 15011 in the first direction X.

In some embodiments, the array substrate further includes an insulation layer between the first common electrode line and the common electrode.

As shown in FIG. 9, the sub-common electrode (not shown) is electrically connected with the second connection portion 15011 through a first via 29 passing through the insulation layer; the orthographic projection of the first via 29 on the base substrate and the orthographic projection of the second connection portion 15011 on the base substrate have an overlapping area.

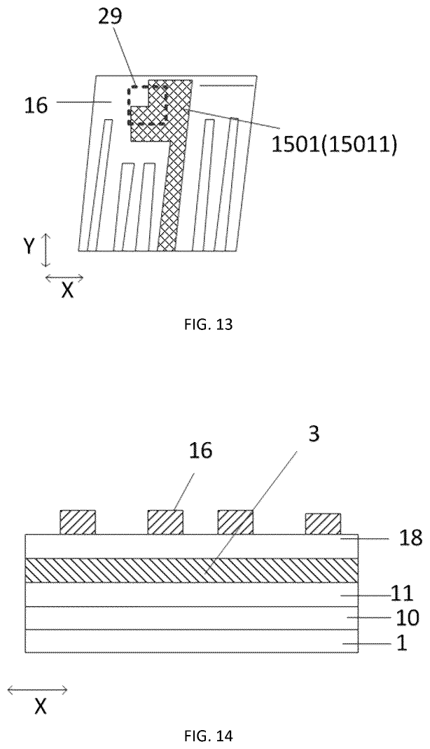

In some embodiments, as shown in FIG. 9, the orthographic projection of the first via 29 on the base substrate does not completely overlap with the orthographic projection of the second connection portion 15011 on the base substrate. That is, the orthographic projection of the first via on the base substrate has an area that does not overlap the orthographic projection of the second connection portion on the base substrate. The via for the electrical connection between the common electrode and the common electrode line is a semi via. The enlarged schematic diagram of area E in FIG. 9 is shown in FIG. 13. FIG. 13 further shows the pattern of the common electrode 16 corresponding to the area E, so as to clarify the orthographic projection relationship between the common electrode 16, the first via 29, and the second connection portion 15011.

In the array substrate provided by embodiments of the disclosure, the via for the electrical connection between the common electrode and the common electrode line is formed using a semi via process. When the array substrate is applied to the liquid crystal display panel, due to the first via is formed using a semi via process, there is a step difference in the thickness of the film layer in the area where the first via is located, which can avoid uneven brightness and chromaticity stripes on the display panel during lighting tests caused by poor liquid crystal alignment.

In some embodiments, the orthographic projection of the first via on the base substrate in the second direction is arranged at a side of the orthographic projection of the first connection portion on the base substrate.

In some embodiments, as shown in FIG. 8, the first area 104 includes a plurality of first area rows 105 extending in the first direction X and arranged in the second direction Y;
the first area line 105 includes a plurality of repeating units 1051 arranged in the first direction X; each repeating unit 1051 includes at least one first sub-area 10511 and at least one second sub-area 10512 arranged along the first direction X; and the first sub-area 10511 and the second sub-area 10512 are arranged between two adjacent data lines 6;
the first thin-film transistor TFT1 is provided in each first sub-area 10511, and the second thin-film transistor TFT2 is provided in each second sub-area 10512.

It should be noted that, in the first one and the last one of the first area rows, only one first thin-film transistor is provided in each first sub-area, only one second thin-film transistor is provided in each second sub-area. In all first area rows except for the first one and last one of the first area rows, and two first thin-film transistors are provided in each first sub-area, and two second thin-film transistors are provided in each second sub-area.

In some embodiments, as shown in FIG. 8, the repeating unit in odd-numbered rows of the first area rows 105 includes m first sub-areas and n second sub-areas, and the repeating unit in even-numbered rows of the first area rows 105 includes n first sub-areas and m second sub-areas;
between two adjacent data lines 6, the first sub-area 10511 and the second sub-area 10512 are alternately arranged in the second direction.

In some embodiments, as shown in FIG. 8, the repeating unit in the odd-numbered rows of the first area rows 105 includes two first sub-areas 10511 and one second sub-area 10512, and the repeating unit in the even-numbered rows of the first area rows 105 includes one first sub-area 10511 and two second sub-areas 10512.

In some embodiments, as shown in FIG. 8, the first pixel electrode 3 and the second pixel electrode 12 are spaced from each other in the first direction X.

In a specific implementation, the area shown in FIG. 8 may be used as a repetition unit of the array substrate.

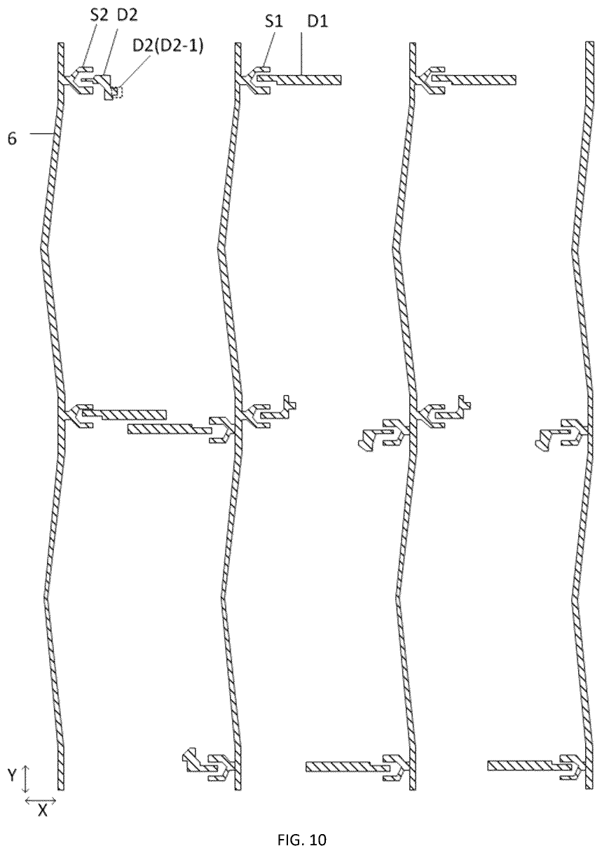

In some embodiments, the scanning line, the first electrode, the fourth electrode, and the common electrode line are arranged in the same layer; the scanning line, the first electrode, the fourth electrode, and the common electrode line are located in the first conductive layer, and the pattern of the first conductive layer is shown in FIG. 9. The data line, the second electrode, the third electrode, the fifth electrode and the sixth electrode are arranged in the same layer; and the data line, the second electrode, the third electrode, the fifth electrode and the sixth electrode are located in the second conductive layer, and the pattern of the second conductive layer is shown in FIG. 10. The first pixel electrode and the second pixel electrode are arranged in the same layer, and the patterns of the two are shown in FIG. 11. The pattern of the common electrode is shown in FIG. 12.

It should be noted that, in the disclosure, “the same layer” refers to the layer structure formed by using the same film forming process to form a film layer for making specific patterns, and then formed through a single composition process using the same mask; here, one composition process corresponds to one mask (also known as a mask). According to different specific patterns, a one-time composition process may include multiple exposure, development or etching processes; and specific patterns in the formed layer structure may be continuous or discontinuous. These specific patterns may be at the same height or have the same thickness, or may be at different heights or have different thicknesses.

In some embodiments, as shown in FIGS. 8 and 10, the sixth electrode D2 includes a convex portion D2-1;
as shown in FIG. 8, an orthographic projection of the convex portion D2-1 on the base substrate and an orthographic projection of the fourth electrode G2 at a side of the first concave area 13 facing away from the fifth electrode S2 on the base substrate have an overlapping area.

It should be noted that, since the sixth electrode and the first conductive layer where the fourth electrode is located have an overlapping area, a capacitance Cgs is formed between the sixth electrode and the first conductive layer. If all the sixth electrodes included in the array substrate shift in the first direction due to process deviation, taking a rightward shift as an example, the overlapping area between the sixth electrode of the second thin-film transistor electrically connected with the first scanning line and the first conductive layer increases; while the overlapping area between the sixth electrode of the second thin-film transistor electrically connected with the second scanning line and the first conductive layer decreases. This will result in different capacitance Cgs formed between different sixth electrodes and the first conductive layer.

In the array substrate provided by embodiments of the disclosure, the sixth electrode includes a convex portion, that is, the sixth electrode overlaps with the fourth electrode at two sides of the first concave area, the capacitance formed between the convex portion and the fourth electrode is Cgs1, and the capacitance formed between the part of the sixth electrode other than the convex portion and the fourth electrode is Cgs2. If all the first pixel electrodes included in the array substrate shift in the second direction due to process deviation, the overlapping area between the convex portion and the fourth electrode increases, the overlapping area between the part other than the convex portion and the fourth electrode decreases, or the overlapping area between the convex portion and the fourth electrode decreases, the overlapping area between the part other than the convex portion and the fourth electrode increases, that is, one of Cgs1 and Cgs2 increases and the other decreases, which can compensate for the influence of process deviation on the capacitance Cgs formed between the sixth electrode and the first conductive layer, and avoid the difference in the capacitances Cgs formed between different sixth electrodes and the first conductive layer, and avoid affecting the display effect.

In specific implementation, as shown in FIG. 5, the thin-film transistor further includes an active layer 17. As shown in FIG. 14, the array substrate further includes a first protective layer 18 between the film layer where the first pixel electrode 3 and the second pixel electrode (not shown) are located and the common electrode 16. FIG. 14 is the cross-sectional view along CC′ in FIG. 8. Thin-film transistor can be of a top-gate structure, or a bottom-gate structure, etc.

In specific implementation, when the thin-film transistor is of the top-gate structure, the gate insulation layer is located between the buffer layer and the first conductive layer, the active layer is located between the buffer layer and the gate insulation layer. The array substrate further includes an interlayer insulation layer between the first conductive layer and the second conductive layer, the second electrode and the third electrode are electrically connected with the conductive area of the active layer of the first thin-film transistor through vias passing through the interlayer insulation layer and gate insulation layer, respectively. The fifth electrode and the sixth electrode are electrically connected with the conductive area of the active layer of the second thin-film transistor through vias passing through the interlayer insulation layer and gate insulation layer, respectively. The insulation layer between the common electrode line and the common electrode includes the first protective layer, the interlayer insulation layer, and the gate insulation layer. The common electrode is electrically connected with the common electrode line through a first via passing through the first protective layer, the interlayer insulation layer, and the gate insulation layer.

In specific implementation, when the thin-film transistor is of the bottom-gate structure, the active layer is arranged at the side of the first conductive layer facing away from the buffer layer, and the gate insulation layer is arranged between the active layer and the first conductive layer; the second electrode and the third electrode are directly lapped with the active layer of the first thin-film transistor. The insulation layer between the common electrode line and the common electrode includes the first protective layer and the gate insulation layer. The common electrode is electrically connected with the common electrode line through a first via passing through the first protective layer and the gate insulation layer.

Next, the first thin-film transistor and the second thin-film transistor as bottom-gate transistors are used as an example to exemplify the process of preparing an array substrate provided by embodiments of the disclosure. First, a buffer layer is formed on a base substrate. Second, a pattern of a first conductive layer is formed on the buffer layer, where the pattern of the first conductive layer is shown in FIG. 9, and a pattern of a mask plate used for the patterning process of the layer corresponds to a pattern of the first conductive layer shown in FIG. 9. Third, a pattern of a gate insulation layer is formed on a side of the active layer facing away from the base substrate. Fourth, a pattern of the active layer is formed on a side of the first conductive layer facing away from the base substrate. Fifth, a pattern of a second conductive layer is formed on a side of the active layer facing away from the base substrate, and a pattern of the second conductive layer is shown in FIG. 10, a pattern of a mask plate used in the patterning process for the layer corresponds to a pattern of the second conductive layer shown in FIG. 10. Sixth, a pattern of a first pixel electrode and a second pixel electrode is formed on the side of the second conductive layer facing away from the base substrate, and the pattern of the film layer is shown in FIG. 11, and the pattern of the mask plate used in the patterning process of the film layer corresponds to the pattern shown in FIG. 11. Seventh, a pattern of a first protective layer is formed on the side of the first pixel electrode and the second pixel electrode facing away from the base substrate. Eighth, a pattern of a common electrode is formed on the side of the first protective layer facing away from the base substrate, and the pattern of the film layer is as shown in FIG. 12.

In specific implementation, the base substrate is, for example, a glass substrate. The materials of the active layer can be amorphous silicon (a-Si), polycrystalline silicon (poly), oxides, such as indium gallium zinc oxide IGZO, etc. The materials of the first conductive layer and the second conductive layer can include copper (Cu), molybdenum (Mo), aluminum (AI), titanium (Ti), chromium (Cr), nickel (Ni) and other metals. The first conductive layer and the second conductive layer can be a single layer structure or a laminated structure, for example, the laminated structure is a laminated structure composed of titanium metal layer/aluminum metal layer/titanium metal layer. In specific implementation, the materials of the first conductive layer and the second conductive layer can be different, for example, the material of the first conductive layer is Cu, and the material of the second conductive layer is Al. Alternatively, it can be set that the materials of the first conductive layer and the second conductive layer are the same, for example, the materials of the first conductive layer and the second conductive layer are both Cu. The materials of the first pixel electrode, the second pixel electrode and the common electrode are the same, for example, transparent conductive materials such as indium tin oxide (ITO), indium zinc oxide (IZO), etc. For example, the materials of buffer layer, gate insulation layer and interlayer insulation layer are at least one of: silicon nitride or silicon oxide. The material of the first protective layer is, for example, Pl.

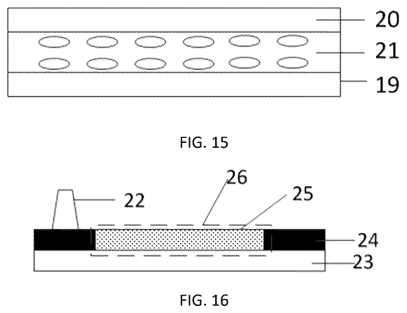

Embodiments of the disclosure provide a display panel, as shown in FIG. 15, the display panel includes:
the array substrate 19 provided by embodiments of the disclosure;
an opposing substrate 20, arranged opposite to the array substrate 19; and
a liquid crystal layer 21, arranged between the array substrate 19 and the opposing substrate 20.

It should be noted that, due to the similarity between the principle of the display apparatus solving the problem and the principle of the array substrate solving the problem mentioned above, the implementation of the display apparatus can refer to the implementation of the array substrate mentioned above, and the repetition will not be repeated.

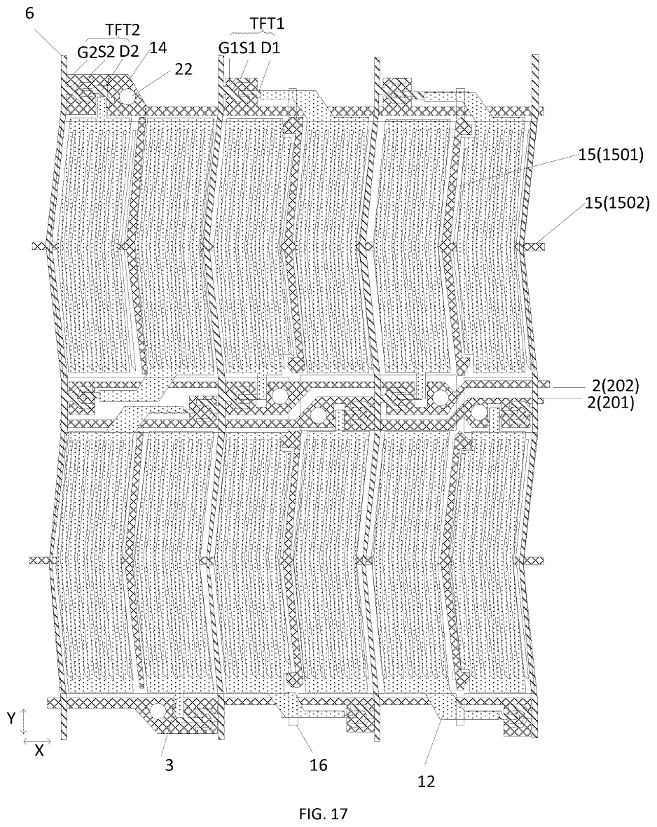

In some embodiments, the array substrate includes a plurality of scanning lines, and the scanning lines includes a plurality of second widening portions;
as shown in FIG. 16, the opposing substrate includes a plurality of spacers 22; as shown in FIG. 17, an orthographic projection of the spacer 22 on the base substrate included in the array substrate is located in an orthographic projection of the second widening portion 205 on the base substrate.

In the specific implementation, the array substrate is further provided with an alignment layer on a side close to the liquid crystal layer and the opposing substrate is further provided with an alignment layer on a side close to the liquid crystal layer.

In specific implementation, the opposing substrate further includes a base substrate. In embodiments of the disclosure, the base substrate included in the array substrate is referred to as the first base substrate, and the base substrate included in the opposing substrate is referred to as the second base substrate. In some embodiments, as shown in FIG. 16, the opposing substrate 19 further includes a black matrix 24 and color resists 25 on the side of the second substrate 23 facing the liquid crystal layer. The black matrix 24 has opening areas 26, and the color resists 25 are arranged in the opening areas 26.

In the specific implementation, the orthographic projection of the black matrix on the array substrate is located within the first area. The color resistors correspond one-to-one with the sub-pixel areas, and the orthographic projection of the color resistor on the array substrate is located within the sub-pixel area. The display panel includes the sub-pixels corresponding one-to-one to the sub-pixel areas, and the sub-pixels include red sub-pixels, blue sub-pixels, and green sub-pixels. Accordingly, the color resists include the red color resists corresponding to the red sub-pixels, the blue color resists corresponding to the blue sub-pixels, and the green color resists corresponding to the green sub-pixels.

Embodiments of the disclosure provide a display apparatus, the display apparatus includes a display panel provided by embodiments of the disclosure.

In some embodiments, in the above-described display apparatus provided in embodiments of the disclosure, the display apparatus further includes a backlight module at the light incident side of the array substrate, and the backlight module may be a direct-lit backlight module or an edge-lit backlight module.

In specific implementation, the edge-lit backlight module may include equal light bars, and stacked reflective sheet, light guide plate, diffusion sheet, prism group, etc. The light bars are located at one side in the thickness direction of the light guide plate. The direct-lit backlight module may include a matrix light source, and a reflective sheet, a diffusion plate, a brightness enhancement film, etc. that are stacked at the light exit side of the matrix light source. The reflective sheet includes openings that are positioned opposite to the positions of each lamp bead in the matrix light source. The lamp beads in the light bars and the lamp beads in the matrix light source can be light-emitting diodes (LEDs), such as micro-light-emitting diodes (Mini LED, Micro LED, etc.). Miniature light-emitting diodes at the sub-millimeter or even micron level are self-luminous devices like organic light-emitting diodes (OLEDs). Like organic light-emitting diodes, it has a series of advantages such as high brightness, ultra-low latency, and ultra-large viewing angle. Moreover, due to the fact that inorganic light-emitting diodes emit light based on metal semiconductors with more stable properties and lower resistance, they have the advantages of lower power consumption, better resistance to high and low temperatures, and longer service life compared to organic light-emitting diodes that emit light based on organic compounds. When micro light-emitting diodes are used as backlight sources, more precise dynamic backlighting effects can be achieved, effectively improving screen brightness and contrast while solving the glare phenomenon caused by traditional dynamic backlighting between bright and dark areas of the screen, optimizing the visual experience.

In some embodiments, the display apparatus according to embodiments of the disclosure may be any product or component having a display function, such as a projector, a three dimensional (3D) printer, a virtual reality device, a mobile phone, a tablet computer, a television, a display, a notebook computer, a digital photo frame, a navigator, a smart watch, a fitness wristband, and a personal digital assistant. Optionally, the display apparatus provided by the disclosure includes but is not limited to: a radio frequency unit, a network module, an audio output-input unit, a sensor, a display unit, a user input unit, an interface unit, a control chip, and other components. In some embodiments, the control chip is a central processing unit, a digital signal processor, a system-on-a-chip (SoC), etc. For example, the control chip may further include a memory, a power module, etc., and power supply and signal input and output functions are achieved through additionally arranged wires and signal lines. For example, the control chip may further include a hardware circuit and a computer executable code. The hardware circuit may include a conventional very large scale integration (VLSI) circuit or a gate array and existing semiconductors such as a logic chip and a transistor or other discrete elements. The hardware circuit may further include a field programmable gate array, a programmable array logic, a programmable logic device, etc. In addition, those skilled in the art can understand that the above structure does not limit the display apparatus according to the embodiment of the disclosure. That is, the display apparatus according to the embodiment of the disclosure may include more or less components, or combine some components, or have different component arrangements.

In summary, embodiments of the disclosure provide an array substrate, a display panel, and a display apparatus, the array substrate includes a first pixel electrode, the first pixel electrode includes a first portion, where the orthographic projection of the first portion on the base substrate overlaps the orthographic projection of the scanning line on the base substrate, and the first pixel electrode further includes a second portion and a third portion arranged at two sides of the scanning line. When both the second portion and the third portion have parasitic capacitance with the scanning line, if there is an offset of all the first pixel electrodes included in the array substrate in the second direction due to a process deviation, compared to the case in which there is no offset, since the second portion and the third portion are respectively arranged at two sides of the scanning line, the parasitic capacitance of one of the second portion and the third portion with the scanning line increases, while the parasitic capacitance of the other one of the second portion and the third portion with the scanning line decreases. Due to the same offset, the absolute value of the change in parasitic capacitance between the second portion and the scanning line and the absolute value of the change in parasitic capacitance between the third portion and the scanning line are the same, that is, the change in parasitic capacitance between the second portion and the scanning line and the change in parasitic capacitance between the third portion and the scanning line are complementary. Even if the position of the first pixel electrode is offset due to process deviation, the parasitic capacitance between each first pixel electrode and the scanning line is still equal, avoiding significant differences in the charging rate of different pixel electrodes caused by different parasitic capacitances between the first pixel electrodes and the scanning line. When the array substrate is applied to display products, it can avoid differences in brightness between different sub-pixel areas. When users move to view display products, it can avoid increasing brightness differences, avoid shake-head stripe, improve display performance, and enhance user experience.

Although the preferred embodiments of the disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of the disclosure.

Evidently those skilled in the art can make various modifications and variations to the disclosure without departing from the spirit and scope of the disclosure. Thus the disclosure is also intended to encompass these modifications and variations therein as long as these modifications and variations to the disclosure come into the scope of the claims of the disclosure and their equivalents.

1-32. (canceled)

33. An array substrate, comprising:
a base substrate, comprising a plurality of sub-pixel areas arranged in an array, and a first area between adjacent sub-pixel areas;
a plurality of scanning lines, at a side of the base substrate and in the first area; wherein the plurality of scanning lines extend in a first direction, and are arranged in a second direction, the first direction intersects with the second direction;
a plurality of first pixel electrodes, at a side of the scanning line facing away from the base substrate; wherein each of the plurality of first pixel electrodes comprises:
a first portion; and
a second portion and a third portion at two sides of the first portion in the second direction;
wherein an orthographic projection of the first portion on the base substrate and an orthographic projection of the scanning line on the base substrate have an overlapping area; and
an orthographic projection of the second portion on the base substrate and an orthographic projection of the third portion on the base substrate are arranged at two sides of the scanning line, respectively.

34. The array substrate according to claim 33, further comprising:
a plurality of first thin-film transistors, in the first area and at a side of the base substrate same as the scanning line; wherein the first thin-film transistor comprises a first electrode, a second electrode, and a third electrode; the first electrode is electrically connected with the scanning line, and the third electrode is electrically connected with the first pixel electrode;
wherein, in the second direction, the third electrode of the first thin-film transistor and the third portion are arranged at the same side of the scanning line connected with the first thin-film transistor; the orthographic projection of the third portion on the base substrate and an orthographic projection of the third electrode on the base substrate have an overlapping area; and the third portion is electrically connected with the third electrode.

35. The array substrate according to claim 34, wherein the third electrode comprises a first strip portion extending in the first direction, and the third portion comprises a second strip portion extending in the first direction; and
an orthographic projection of the second strip portion on the base substrate and an orthographic projection of the first strip portion on the base substrate have an overlapping area.

36. The array substrate according to claim 35, wherein the orthographic projection of the second strip portion on the base substrate covers the orthographic projection of the first strip portion on the base substrate.

37. The array substrate according to claim 36, wherein the second strip portion wraps around a side surface of the first strip portion.

38. The array substrate according to claim 35, wherein at least one of following is comprised:
the orthographic projection of the third portion on the base substrate and an orthographic projection of the first electrode on the base substrate do not overlap with each other; or
in the first direction, the second portion and the third portion are respectively arranged at two sides of the first portion.

39. The array substrate according to claim 35, wherein the plurality of sub-pixel areas are divided into a plurality of sub-pixel area columns, and the plurality of sub-pixel area columns extend in the second direction and are arranged in the first direction;
the orthographic projection the first strip portion on the base substrate passes through an area between two adjacent sub-pixel area columns;
in the first pixel electrode and the first thin-film transistor electrically connected with each other, the first electrode and the second portion correspond to two different sub-pixel area columns that adjacent to each other, respectively.

40. The array substrate according to claim 39, further comprising:
a plurality of data lines in the first area, wherein the plurality of data lines are arranged between the scanning lines and the pixel electrodes in a direction perpendicular to the base substrate; the plurality of data lines extend in the second direction, and arranged in the first direction; two sub-pixel area columns are located between two adjacent data lines, and the second electrode is electrically connected with the data line; and
the first thin-film transistor and the first pixel electrode electrically connected with the first thin-film transistor are located between the two adjacent data lines;
wherein the plurality of scanning lines comprise a plurality of first scanning lines and a plurality of second scanning lines; the first scanning line and the second scanning line are arranged alternately; and one first scanning line and one second scanning line are arranged between two adjacent sub-pixel areas in the second direction; and
between two adjacent data lines and in the first area, two first pixel electrodes respectively corresponding to adjacent first scanning line and second scanning line are located in different sub-pixel area columns.

41. The array substrate according to claim 39, wherein, between two adjacent data lines and in the first area corresponding to the first thin-film transistor, the scanning line comprises a third strip portion extending in the first direction; and
an edge of the second portion close to the third strip portion is parallel to the third strip portion;
in the second direction, a distance between the third portion and the scanning line is approximately equal to a distance between the second portion and the scanning line.

42. The array substrate according to claim 41, wherein an edge of the first electrode close to the third portion is perpendicular to the third strip portion;
between two adjacent said data lines and between two adjacent sub-pixel area rows, two first electrodes electrically connected with the first scanning line and the second scanning line respectively are arranged opposite to each other in the first direction; an orthographic projection of the first strip portion on the base substrate and the orthographic projection of the second strip portion on the base substrate are located between orthographic projections of the two first electrodes opposite to each other on the base substrate;
and/or
the scanning line further comprises: a first widening portion connected with the third strip portion in the second direction; and the first widening portion is arranged at the same side of the third strip portion as the third portion.

43. The array substrate according to claim 40, further comprising:
a plurality of second thin-film transistors, wherein each second thin-film transistor comprises a fourth electrode, a fifth electrode and a sixth electrode; a length of the sixth electrode is less than a length of the third electrode in the first direction; the fourth electrode is electrically connected with the scanning line, and the fifth electrode is electrically connected with the data line; and
a plurality of second pixel electrodes; wherein an orthographic projection of the second pixel electrode on the base substrate and the orthographic projection of the scanning line on the base substrate do not overlap with each other; and the second pixel electrode is electrically connected with the sixth electrode;
wherein the second pixel electrode and the second thin-film transistor electrically connected with the second pixel electrode correspond to a same one sub-pixel area column.

44. The array substrate according to claim 43, wherein, between two adjacent data lines and in the first area corresponding to the second thin-film transistor, a pattern of an orthographic projection of the fourth electrode on the base substrate has a first concave area;
an orthographic projection of the sixth electrode on the base substrate and the first concave area have an overlapping area, and the sixth electrode is electrically connected with the second pixel electrode in the first concave area;
the sixth electrode comprises a convex portion, an orthographic projection of the convex portion on the base substrate and an orthographic projection of the fourth electrode at a side of the first concave area facing away from the fifth electrode on the base substrate have an overlapping area.

45. The array substrate according to claim 44, wherein, between two adjacent data lines and in the first area corresponding to the second thin-film transistor, the scanning line comprises: a second widening portion, and a fourth strip portion extending in the first direction;
wherein the fourth electrode and the second widening portion are respectively at two sides of the first concave area in the first direction, and the fourth strip portion is arranged at a side of the second widening portion facing away from the first concave area; and
a width of the second widening portion is greater than a width of the fourth strip portion in the second direction;
wherein, between two adjacent data lines and in the first area corresponding to at least part of the second thin-film transistors, the scanning line further comprises: a fifth strip portion connected with the second widening portion and the fourth strip portion;
an angle between an extension direction of the fifth strip portion and the first direction is greater than 0, and an angle between the extension direction of the fifth strip portion and the second direction is greater than 0;
a pattern formed by an orthographic projection of the second widening portion on the base substrate and an orthographic projection of the fifth strip portion on the base substrate has a second concave area;
an orthographic projection of the second concave area on the base substrate and the orthographic projection of the fifth strip portion on the base substrate overlap with an area between two adjacent sub-pixel area columns.

46. The array substrate according to claim 45, wherein, between two adjacent data lines and in the first area corresponding to at least part of the second thin-film transistors, the second widening portion is connected with the fourth strip portion; and
at a side of the scanning line close to the sub-pixel area, an edge of the second widening portion is located in the same straight line as an edge of the fourth strip portion;
and/or
a maximum width of the second widening portion is equal to a width of the fourth electrode in the second direction.

47. The array substrate according to claim 45, further comprising: common electrode lines, and a common electrode electrically connected with the common electrode lines;
wherein common electrode lines comprises: a plurality of first common electrode lines extending in the second direction; an orthographic projection of the first common electrode line on the base substrate is located between two adjacent sub-pixel areas in the first direction;
the common electrode comprises: a plurality of sub-common electrodes, and a plurality of first connection portions;
the sub-commons electrodes correspond to sub-pixel area rows, the first connection portion extends in the second direction, and the first connection portion is electrically connected with the sub-commons electrode.

48. The array substrate according to claim 47, wherein the orthographic projection of the scanning line on the base substrate comprises a second concave area, an orthographic projection of at least part of the first connection portions on the base substrate and the orthographic projection of the second concave area on the base substrate have an overlapping area;
the scanning line comprises the second widening portion, the orthographic projection of at least part of the first connection portions on the base substrate and the orthographic projection of second widening portion on the base substrate have an overlapping area.

49. The array substrate according to claim 47, wherein at least part of the first common electrode lines comprises: a second connection portion;
the second connection portion is arranged at an end of the first common electrode line in an extension direction of the first common electrode;
the array substrate further comprises an insulation layer between the first common electrode line and the common electrode;
the sub-common-electrode is electrically connected with the second connection portion through a first via passing through the insulation layer; and
an orthographic projection of the first via on the base substrate does not completely overlap with an orthographic projection of the second connection portion on the base substrate.

50. The array substrate according to claim 43, wherein the first area comprises a plurality of first area rows extending in the first direction and arranged in the second direction;
each first area row comprises: a plurality of repeating units arranged in the first direction; each repeating unit comprises at least one first sub-area and at least one second sub-area arranged in the first direction, both the first sub-area and the second sub-area are located between two adjacent data lines; and
the first thin-film transistor is provided in each first sub-area, and the second thin-film transistor is provided in each second sub-area.

51. The array substrate according to claim 50, wherein the repeating unit in odd-numbered rows of the first area rows comprises m first sub-areas and n second sub-areas, and the repeating unit in even-numbered rows of the first area rows comprises n first sub-areas and m second sub-areas;
between two adjacent data lines, the first sub-area and the second sub-area are alternately arranged in the second direction;
the repeating unit in the odd-numbered rows of the first area rows comprises two first sub-areas and one second sub-area, and the repeating unit in the even-numbered rows of the first area rows comprises one first sub-area and two second sub-areas.

52. A display panel, comprising:
the array substrate according to claim 33;
an opposing substrate, arranged opposite to the array substrate; and
a liquid crystal layer, arranged between the array substrate and the opposing substrate;
wherein the plurality of scanning lines comprised in the array substrate comprise a plurality of second widening portions;
the opposing substrate comprises a plurality of spacers; and
an orthographic projection of the spacer on the base substrate comprised in the array substrate is located within an orthographic projection of the second widening portion on the base substrate.
